(19) United States
(12) Patent Application Publication
(10) Pub. No.: US 2024/0243230 A1
(43) Pub. Date: Jul. 18, 2024

(54) LIGHT EMITTING ELEMENT

(71) Applicant: TOYODA GOSEI CO., LTD., Kiyosu-shi (JP)

(72) Inventors: Hideki OMOYA, Kiyosu-shi (JP); Shinichi MATSUI, Kiyosu-shi (JP); Hiroaki MAKINO, Kiyosu-shi (JP); Koichi MIZUTANI, Kiyosu-shi (JP)

(21) Appl. No.: 18/540,106

(22) Filed: Dec. 14, 2023

(30) Foreign Application Priority Data
Jan. 17, 2023 (JP) 2023-005400

(51) Int. Cl. H01L 33/38; H01L 33/32; H01L 33/46; H01L 33/56

(52) U.S. Cl. CPC H01L 33/382; H01L 33/32; H01L 33/46; H01L 33/56

(57) ABSTRACT

A light emitting element having an emission wavelength of 200 to 280 nm and including a group-III nitride semiconductor containing Al. The element includes a p-electrode provided on the p-type layer in contact therewith, including a Ru layer, an n-electrode provided on the n-type layer exposed at a bottom of a hole, and a protective film covering an entire upper surface of the element and including a first protective film made of SiO₂ and a second protective film made of SiN which are laminated in sequence.

### CROSS-REFERENCE

This application claims priority to Japanese patent application No. 2023-005400 filed on Jan. 17, 2023, the contents of which are fully incorporated herein by reference.

### TECHNICAL FIELD

The present disclosure relates to a light emitting element.

### BACKGROUND ART

In recent year, ultraviolet LEDs for use in sterilization/antisepsis of water, air, etc. have drawn a lot of attention, and research and development of high-efficiency ultraviolet LED have been actively advanced.

In the past, for a group-III nitride semiconductor light emitting element for blue light emission and near-ultraviolet light emission, p-GaN has been used to form a p-type contact layer with which a p-electrode is in contact to thereby reduce a contact resistance. However, in the case of a group-III nitride semiconductor light emitting element having an emission wavelength of UVC (wavelength: 200 to 280 nm), p-AlGaN has been under consideration for use as a p-type contact layer. This is because p-GaN absorbs ultraviolet rays, and thus cannot achieve a satisfactory light extraction efficiency.

Besides, in the past, for the group-III nitride semiconductor light emitting element for blue light emission and near-ultraviolet light emission, ITO (Indium Tin Oxide) and a DBR (Distributed Bragg Reflector) have been used as a reflecting electrode formed on the p-type contact layer. However, the group-III nitride semiconductor light emitting element having an emission wavelength of UVC had no ability to fully reflect ultraviolet rays, which resulted in large irradiation loss. For this reason, materials having higher ultraviolet reflectance, for example, Rh, Ru, Al, etc. have been targeted to be used as the reflecting electrode.

In general, SiO₂ has been used for the protective film of a group-III nitride semiconductor light emitting element. JP-A-2011-233783, JP-A-2001-160650, and JP-A-2006-41403 describe that SiN/SiO₂ is used as a protective film. Here, “/” (oblique stroke) represents lamination, specifically speaking, “A/B” represents a laminated structure in which A is laminated on B. This explanation will be applied to the description of the materials below.

In addition, Japanese Patent No. 6331204 has a description that AlGaN is not resistant to moisture. The literature describes that moisture infiltrates from a pinhole and/or a crack of a passivation film to reach the surface of an AlGaN layer, so that AlN in AlGaN is decomposed by the moisture, and Al is oxidized to form Al₂O₃.

### SUMMARY

In the case of using a UVC light emitting element for water sterilization, the moisture resistance of the light emitting element is key. In a UVC light emitting element having a p-type contact layer made of p-AlGaN and a p-electrode made of Rh, Ru, or Al, however, it was found that a defect occurs in electric property in a humidity test when using SiO₂ as a protective film and the quality cannot be guaranteed accordingly. The reason can be considered that AlGaN is not resistant to moisture as shown in Japanese Patent No. 6331204, that Al causes electromigration, and that Ru tends to easily react with oxygen to thereby generate gas, and so on.

Moreover, in the UVA light emitting element at present, light emission efficiency is low while a large amount of heat is generated, and thus the life span of the element is shorter than a blue light emission element. For this reason, there has been a demand for a protective film having a higher heat dissipation property.

The present disclosure has been made in view of such a background, and an object of the invention is to provide a light emitting element including a group-III nitride semiconductor and having a protective film suitable for UVC.

One aspect of the disclosure is a light emitting element having an emission wavelength of 200 to 280 nm and including a group-III nitride semiconductor containing Al, the element, comprising:
a substrate;
a semiconductor layer including an n-type layer, a light emitting layer, and a p-type layer which are laminated on the substrate in this order;
a hole provided on a predetermined region of a surface of the p-type layer, the hole having a depth reaching the n-type layer;
a p-electrode provided on the p-type layer in contact therewith, the p-electrode including one of a Ru layer, a Rh layer, a Ni Layer, and an ITO layer;
an n-electrode provided on the n-type layer exposed at a bottom of the hole;
a protective film covering an entire upper surface of the element, the protective film including a first protective film made of SiO₂ and a second protective film made of SiN which are laminated in this order from a side of the substrate.

In the above-mentioned light emitting element, a protective film has a structure in which SiO₂ and SiN are laminated in sequence. Because SiN is of high density and has less defects in comparison with SiO₂, a moisture proof property of the protective film can be improved. Further, SiN has a thermal conductivity higher than that of SiO₂, and thus a heat dissipation property of the protective film can be improved. Furthermore, because SiN has an insulation property higher than that of SiO₂, an insulation property of the protective film can be improved. Still furthermore, due to the laminated structure, SiO₂ and SiN act to cancel a film stress, so that reduction of the film stress can be achieved.

As mentioned above, the above-mentioned aspect can provide a light emitting element including a group-III nitride semiconductor and having a protective film suitable for UVC.

### BRIEF DESCRIPTION OF THE DRAWINGS

FIG. 1 shows a cross section vertical to a substrate of a light emitting element according to an embodiment to illustrate the structure of the light emitting element.

FIG. 2 shows a planer pattern of an electrode.

FIG. 3 shows a step of manufacturing the light emitting element according to the embodiment.

FIG. 4 shows a step of manufacturing the light emitting element according to the embodiment.

FIG. 5 shows a step of manufacturing the light emitting element according to the embodiment.

FIG. 6 shows a step of manufacturing the light emitting element according to the embodiment.

FIG. 7 shows a step of manufacturing the light emitting element according to the embodiment.

FIG. 8 shows a step of manufacturing the light emitting element according to the embodiment.

FIG. 9 shows a step of manufacturing the light emitting element according to the embodiment.

FIG. 10 is a graph showing a wet etching rate of each sample.

FIG. 11 is a graph showing a film stress of each sample.

FIG. 12 is a photograph of the surface of the substrate on which an Ag nano-paste has been applied.

FIG. 13 is a graph showing a relation between an applied voltage and an insulation resistance value in each sample.

FIG. 14 is a graph showing a relation between an applied voltage and an insulation resistance value in each sample having an Ag nano paste applied thereto.

FIG. 15 is a graph showing a relation between an applied voltage and an insulation resistance value in each sample having an Ag film deposited thereon.

FIG. 16 is a graph showing a relation between an applied voltage and an insulation resistance value in each sample having a Ti film deposited thereon.

### DETAILED DESCRIPTION OF THE EMBODIMENTS

A light emitting element has an emission wavelength of 200 to 280 nm and includes a group-III nitride semiconductor containing Al. Furthermore, the light emitting element includes a substrate, a semiconductor layer including an n-type layer, a light emitting layer, and a p-type layer which are laminated on the substrate in this order, a hole provided in a predetermined region of a surface of the p-type layer in a depth reaching the n-type layer, a p-electrode that is provided on the p-type layer in contact therewith and includes one of a Ru layer, a Rh layer, an Ni Layer, and an ITO layer, an n-electrode provided on the n-type layer exposed at the bottom of the hole, and a protective film that covers an entire upper surface of the element and includes a first protective film made of SiO₂ and a second protective film made of SiN which are laminated in this order from a side of the substrate. Throughout the specification, the word “on” is used not only in the case of direct lamination (two objects are in contact with each other) but also in the case of indirect lamination (two objects have something interposed therebetween), unless otherwise noted.

The light emitting element may comprise between the first protective film and the second protective film a reflection film including Al.

The hole may be formed plurally and a plurality of the holes are arranged in a pattern of a lattice. The n-electrode may be formed on a bottom of each hole.

The second protective film may have a thickness of 320 nm or more. Besides, a thickness ratio of the second protective film to the first protective film may fall within a range of 0.5 to 2.

The n-electrode may include a first layer at a position in contact with the n-type layer, the first layer being made of AlNₓ, or Al_{y}Ga_{1-y}Nₓ having an Al composition higher than that of the n-type layer and having a thickness of 1 nm or more and 3 nm or less, and a second layer at a position in contact with the first layer, the second layer being made of metal including Al as a main component and V and having a thickness of 50 nm or more and 500 nm or less.

The light emitting element may be used for water sterilization or air sterilization in a high-humidity environment.

### Embodiment

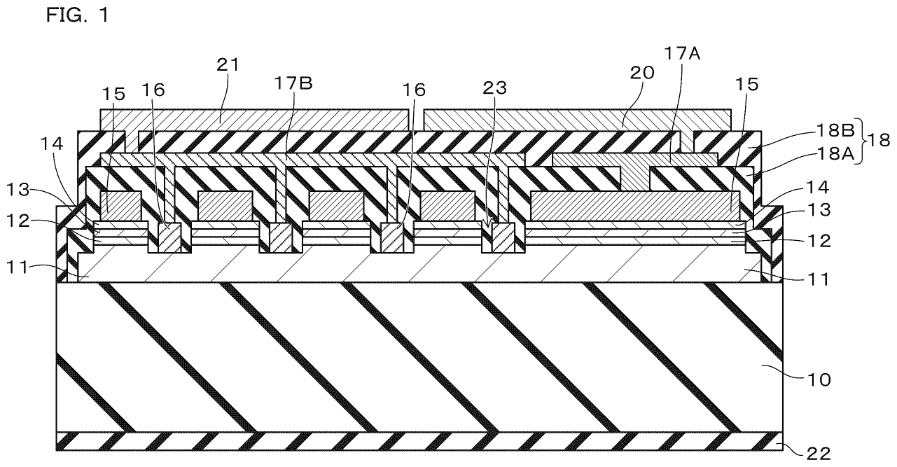

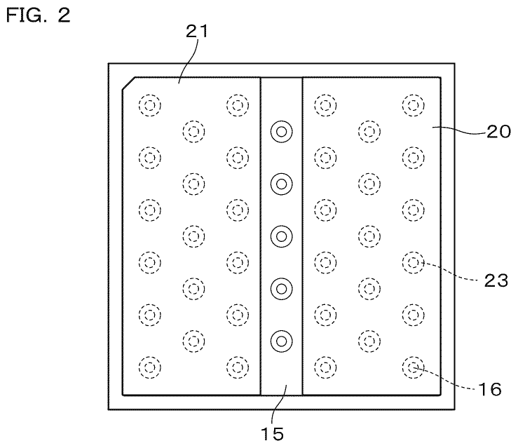

FIG. 1 shows a cross section vertical to a substrate of a light emitting element according to an embodiment to illustrate the structure of the light emitting element. FIG. 2 shows a planer pattern of an electrode of the light emitting element according to the embodiment. The light emitting element of the embodiment is a flip-chip ultraviolet light emitting element, the emission wavelength of which is in the UVC wavelength region and is, for example, 200 to 280 nm.

### 1. Components of the Light Emitting Element

FIG. 1 shows that the light emitting element according to the embodiment includes a substrate 10, a n-type layer 11, a light emitting layer 12, an electron block layer 13, a p-type layer 14, a p-electrode 15, an n-electrode 16, PN electrodes 17A and 17B, a protective film 18, a reflection film 19, a p-pad electrode 20, an n-pad electrode 21, and an antireflection film 22. An explanation of each component will be described below.

The substrate 10 is made of sapphire having a c-surface set as the principal surface. Any material other than sapphire, which has a high transmission and can grow a group-III nitride semiconductor, can be used for the substrate.

A backside of the substrate 10 (the surface on the side opposite to the n-type layer 11 side, corresponding to a light extraction side) is provided with the antireflection film 22. The antireflection film 22 thus provided prevents ultraviolet rays from reflecting on the backside of the substrate 10 and returning to the element side to thereby improve light extraction performance. The antireflection film 22 is made of SiO₂, and the thickness is, for example, one-fourth of the emission wavelength.

The n-type layer 11 is located on the substrate 10 through a buffer layer (not shown in the figure). The n-type layer 11 is made of n-AlGaN. An n-type impurity is Si, the concentration of which is in the range of 5×10¹⁸ to 5×10¹⁹/cm³. The n-type layer 11 may be multilayered.

The light emitting layer 12 is located on the n-type layer 11. The light emitting layer 12 has a MQW (Multiple Quantum Well) structure in which a well layer and a barrier layer are laminated in turn repeatedly. The number of repetition is, for example, 2 to 5. The well layer is made of AlGaN in which an Al composition is set depending on an intended emission wavelength. The barrier layer is made of AlGaN an Al composition of which is higher than that in the well layer. AlGaN having a band gap energy higher than that of the well layer may be employed. The light emitting layer 12 may have a SQW (Single Quantum Well) structure.

The electron block layer 13 is located on the light emitting layer 12. The electron block layer 13 is made of p-AlGaN having an Al composition higher than that in the barrier layer of the light emitting layer 12. The electron block layer 13 prevents electrons injected from the n-electrode 16 from passing through the light emitting layer 12 and diffusing into the p-type layer 14 side.

The p-type layer 14 is located on the electron block layer 13. The p-type layer 14 is made of p-AlGaN. In the light emitting element according to the embodiment, all of the n-type layer 11 through the p-type layer 14 as the semiconductor layer are made of AlGaN, and thus the semiconductor layer is prevented from absorbing ultraviolet light. The p-type layer 14 has an Al content of 5 to 80%, for example. Mg is contained as a p-type impurity. The concentration of Mg is 1×10¹⁹/cm³ or higher. The p-type layer 14 may be formed of a plurality of layers having different Al composition and Mg concentration from each other. In this case, the layer in contact with the p-electrode 15 only needs to be made of p-AlGaN of which the Al content is 5 to 80%. Besides, not only AlGaN but a group-III nitride semiconductor containing Al may be adopted for the p-type layer 14. AlGaInN may be adopted as well.

In a partial region on the surface of the p-type layer 14, holes 23 having a depth reaching the n-type layer 11 are formed. Arrangement of the holes 23 are dot-like, and specifically a plurality of the holes 23 are provided in the region, being arranged in a pattern of a lattice (see FIG. 2). The n-type layer 11 is exposed at the bottom of the holes 23. The holes 23 for exposing the n-type layer 11 are arranged in a dot-like pattern so that reduction in light emission area (an area of the p-type layer 14) is lessened as much as possible while surely achieving uniformity of light emission on the surface to thereby improve light output.

A planer pattern of each hole 23 is, for example, circle. Other than circle, any polygon such as regular hexagon is also acceptable. In the case of regular hexagon, the side surface of the hole 23 is preferably a m-plane. The holes 23 are arranged in a pattern of a square lattice, a triangular lattice, or a honeycomb, for example.

The p-electrode 15 is provided on the p-type layer 14. The p-electrode 15 is provided in the region where the holes 23 are not formed and the region except end vicinal portions of the p-type layer 14 (see FIG. 2) to thereby ensure a broad light emission area. The p-electrode 15 is a reflecting electrode by which ultraviolet rays emitted from the light emitting layer 12 is reflected to the substrate 10 side to thereby heighten light extraction efficiency. The p-electrode 15 is made of a material having a low-contact resistance to the p-type layer 14 and having a high UVC reflectance. Examples of the material include Rh and Ru. Also a lamination of Ni or ITO with a reflecting layer is appropriate.

A ratio of the area of the p-electrode 15 to the area of the upper surface of the element (a total area of the holes 23 and the p-type layer 14) is set to 70% or more. Planer patterns of the holes 23 and the p-electrode 15 are determined to meet the abovementioned condition. For this purpose, for example, the diameter, number of arrays, and distance of arrays of the holes are adjusted. By allowing the p-electrode 15 made of Ru to occupy a large area of the surface, reflection of ultraviolet rays by the p-electrode 15 can be increased to thereby improve the light extraction efficiency. The ratio is preferably set to 80% or more.

The n-electrodes 16 are provided on the n-type layer 11 exposed at the bottom of each hole 23. Therefore, the n-electrodes 16 are also arranged in a dot-like pattern (see FIG. 2). The n-electrodes 16 is constituted by a structure made of heat-treated V/Al/Ti. Also, Ti/Al/Ti etc. is applicable. The structure made of heat-treated V/Al/Ti is, specifically, structured by laminating a layer made of AlNₓ, a layer made of metal including Al as a main component, V, and Ti, and a layer made of Ti in sequence.

The layer made of AlNₓ has a thickness of 1 to 3 nm. For example, a numerical value applied to a symbol x may be, for example, 0.4 to 0.7 A. In this regard, x may decrease in number as the distance from the n-type layer 11 increases in the thickness direction. In this case, the average value of x in the thickness direction is 0.4 to 0.7. In some cases, Ga may diffuse from the n-type layer side. In such cases, the layer is made of Al_{y}Ga_{1-y}Nₓ (0.4≤x≤0.7) having a Al composition higher than that of the n-type layer 11. When defining the Al composition of the n-type layer 11 as a symbol a, the relational expression of a≤y≤1 is satisfied. The numerical value of y is, for example, 0.7 or more. Also in this case, x may decrease in number as the distance from the n-type layer 11 increases in the thickness direction, and y may increase in number as the distance from the n-type layer 11 increases in the thickness direction.

The layer made of a metal including Al as a main component, V, and Ti has a thickness of 50 to 500 nm. As for the ratio of Al, V, and Ti, for example, an Al content is 50 to 85 mol %, a V content is 5 to 20 mol %, and a Ti content is 10 to 30 mol %.

In the n-electrode 16 having the above-mentioned structure, the contact resistance to the n-type layer 11 is reduced. For example, the contact resistivity of the n-electrode 16 to the n-type layer 11 is 4×10⁻⁴ Ω·cm² or less. This is considered firstly because the layer of AlNₓ functions as a contact layer appropriate for the n-type layer 11. Secondly, this is considered because nitrogen vacancies are generated on the surface of the n-type layer 11, so that the surface of the n-type layer 11 becomes n-type, and thus the contact resistance decreases.

The layer made of Ti is provided as a cover to prevent Al contained in the n-electrode 16 from vaporizing at the time of alloying. Other than Ti, TiN, Ni, Pt, Au, etc., are applicable.

The protective film 18 is provided over an entire upper surface of the element. In other words, the protective film 18 is provided continuously over the side and upper surfaces, respectively, of the p-electrode 15 and the n-electrode 16, the side and upper surfaces of the semiconductor layer, the side surface of the element isolation trench 26, and the inside of holes 23.

The protective film 18 is structured such that a first protective film 18A made of SiO₂ and a second protective film 18B made of SiN are laminated in sequence. Such a two-layered structure has the following advantages, and is therefore suitable for a UVC light emitting element.

Firstly, the two-layered structure can improve the moisture proof property of the protective film 18. The reason for the improvement is described below. SiO₂ formed by sputtering or vapor deposition has defects such as pinhole or the like. Moisture infiltrates through this defect to reach the underneath of the protective film 18, therefore when the protective film 18 is formed of a single layer of SiO₂, the moisture proof property is poor.

In contrast, SiN is of high density and has less defects in comparison with SiO₂. Focusing attention on this point, the first protective film 18B made of SiN is provided on the first protective film 18A made of SiO₂ so that the defect is disconnected at the interface between the first protective film 18A and the second protective film 18B in order not to continue the defect in the first protective film 18A to the second protective film 18B. As a result, defects continuous from the first protective film 18A to the second protective film 18B are reduced to thereby prevent moisture from passing through the defects in the protective film 18 and infiltrating the underneath of the protective film 18. AlGaN constituting the light emitting element is not resistant to moisture, but can be appropriately protected by the protective film 18 having a high moisture proof property.

Secondly, the heat dissipation property of the protective film 18 can be improved. Since the thermal conductivity of SiO₂ is 1.4 W/m·K and the thermal conductivity of SiN is 24 W/m·K, SiN is higher than SiO₂ in thermal conductivity. Therefore, in comparison with the case of a protective film 18 formed as a single layer made of SiO₂, the thermal conductivity can be higher in the two-layer structured protective film 18. A UVC light emitting element at present is low in light emission efficiency and large in heat generation, however, the protective film makes it possible to efficiently perform heat radiation to the outside of the element. Thus, the service life of the element can be improved accordingly.

Thirdly, the film stress of the protective film 18 can be reduced. In SiO₂, a compression stress generates in an in-plane direction while in SiN, a tensile stress generates in an in-plane direction, therefore lamination structure formed of SiO₂ and SiN can act on cancelation of the film stress. As the result, peeling and/or cracking of the protective film 18 can be prevented to thereby achieve improved reliability.

Fourthly, insulation of the protective film 18 can be raised. The insulation resistance value of SiN is higher than that of SiO₂. Therefore, the lamination structure of SiO₂ and SiN makes it possible to obtain insulation higher than that in the case of a single layer made of SiO₂. In the comparison under the condition of the same thickness, SiN is twice SiO₂ in withstand pressure. In addition, when the thickness of SiN is made twice, the withstand pressure can be made approximately twice.

The thicknesses of the first protective film 18A and the second protective film 18B are preferably set such that the stresses in in-plane direction are mutually canceled. For example, the sum of the stress in the first protective film 18A and the stress in the second protective film 18B are set to −50 to 50% of the stress in the first protective film 18A. Because the film stresses in the first protective film 18A and the second protective film 18B are determined depending on the conditions of respective thicknesses, depositing methods, depositing conditions, etc., the thicknesses of the first protective film 18A and the second protective film 18B are set according to these conditions. The thickness ratio of the second protective film 18B to the first protective film 18A is set to, for example, 0.5 to 2. In addition, from the viewpoint of insulation, the thickness of the second protective film 18B is preferably set to 320 nm or more, and more preferably set to 640 nm or more. Although the thickness of the second protective film 18B has no specific upper limit, it is preferably set to 2 μm or less in view of deposition time, and so on. The thickness of the first protective film 18A is preferably set to 320 to 2000 nm in view of sure insulation, deposition time, and so on.

A refractive index of SiN can be varied by changing the depositing condition to vary the composition ratio of Si and N. The refractive index may be varied, for example, in the range of 1.2 to 1.3. The light emitting element is sealed with a sealing material with which the second protective film 18B is in contact. The refractive index of the second protective film 18B is adjusted in correspondence with the refractive index of the sealing material to match the refractive indexes between the sealing material and the first protective film 18A, so that the light extraction efficiency can be improved.

The PN electrodes 17A and 17B are respectively provided between the first protective film 18A and the second protective film 18B. It is noted that FIG. 2 does not show these PN electrodes. The PN electrode 17A connects to the p-electrode 15 through the hole formed in the first protective layer 18A. The PN electrode 17B connects to each of the n-electrodes 16 through the hole formed in the first protective layer 18A. A material for the PN electrodes 17A and 17B is, for example, Ti/Ni/Au/Al.

A reflection film including Al may be provided between the first protective film 18A and the second protective film 18B and in a region spaced from the PN electrodes 17A and 17B. The reflection film reflects the light to the substrate 10 side and makes it possible to improve light extraction efficiency. In addition, the reflection film makes it possible to improve heat dissipation property of the protective film 18. The reason why the reflection film is embedded in the protective film 18 is for the purpose of preventing migration.

A material for the reflection film is not limited to Al, and any material having high reflectance in emission wavelength can be used. An alloy mainly composed of Al is applicable. The reflection film may be provided inside the first protective film 18A and/or the second protective film 18B instead of providing between the first protective film 18A and the second protective film 18B. When providing a plurality of the reflection films, the planer pattern may be changed.

Although the protective film 18 of the embodiment is formed of two layers including the first protective film 18A and the second protective film 18B, an additional layer may be provided on the second protective film 18B.

The p-pad electrode 20 and the n-pad electrode 21 are provided separately on the protective film 18. The p-pad electrode 20 is connected to the PN electrodes 17A through a hole formed through the second protective film 18B. The n-pad electrode 21 is connected to the PN electrodes 17B through a hole formed through the second protective film 18B. A material for the p-pad electrode 20 and the n-pad electrode 21 is, for example, Ti/Pt/AuSn.

As mentioned above, the light emitting element according to the embodiment includes the protective film 18 structured to laminate the first protective film 18A made of SiO₂ and the second protective film 18B made of SiN. This configuration makes it possible to improve the moisture resistance, the heat dissipation property, and the insulation property and to reduce the film stress of the protective film 18.

In the light emitting element according to the embodiment, the emission wavelength is in the UVC wavelength region, the semiconductor layer including the n-type layer 11, the light emitting layer 12, the electron block layer 13, and the p-type layer 14 is entirely made of AlGaN to prevent absorption of ultraviolet light. In this regard, it is noted that the p-type layer 14, the upmost layer is also made of AlGaN. Because AlGaN is not resistant to moisture, it is necessary to protect AlGaN (particularly in the p-type layer 14 as an uppermost layer) from having contact with moisture from the outside of the element. The protective film 18 of high moisture proof property can appropriately protect AlGaN.

The light emitting element according to the embodiment is excellent in moisture resistance as mentioned above, and thus it is suitably used for water sterilization and air sterilization in a high-humidity environment.

### 2. Manufacturing Process of the Light Emitting Element

The manufacturing processes of the light emitting element according to the embodiment will be described with reference to the figures.

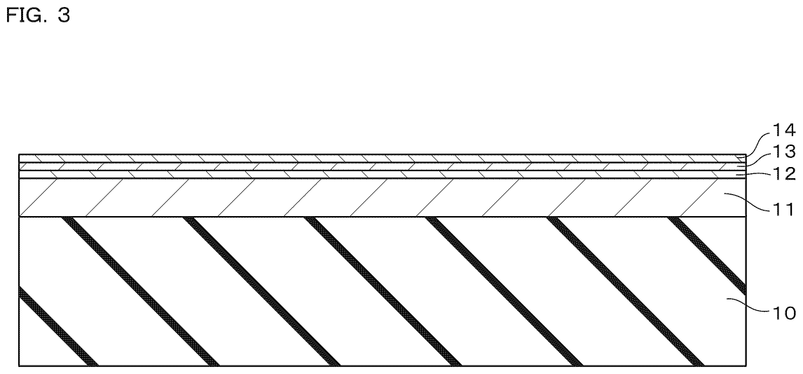

First, the substrate 10 made of sapphire is prepared. Then, the n-type layer 11, the light emitting layer 12, the electron block layer 13, and the p-type layer 14 are sequentially formed on the substrate 10 by the MOCVD method (see FIG. 3).

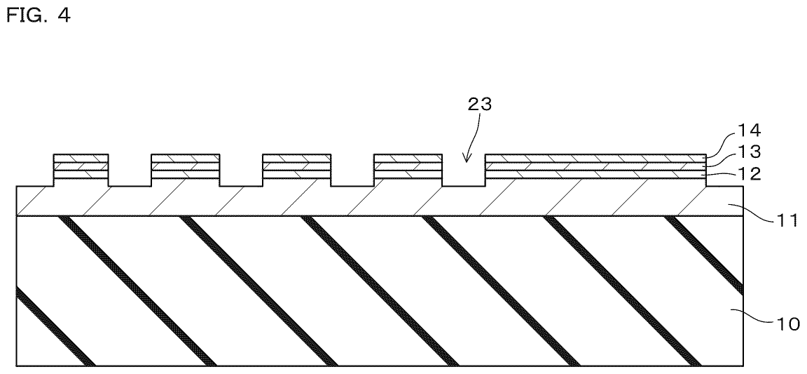

Then, a predetermined region of the p-type layer 14 is subjected to dry etching to form a plurality of the holes 23 each having a depth which reaches the n-type layer 11 (see FIG. 4).

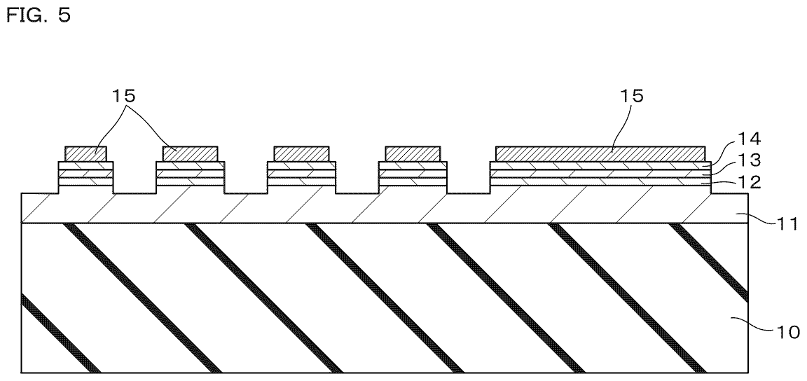

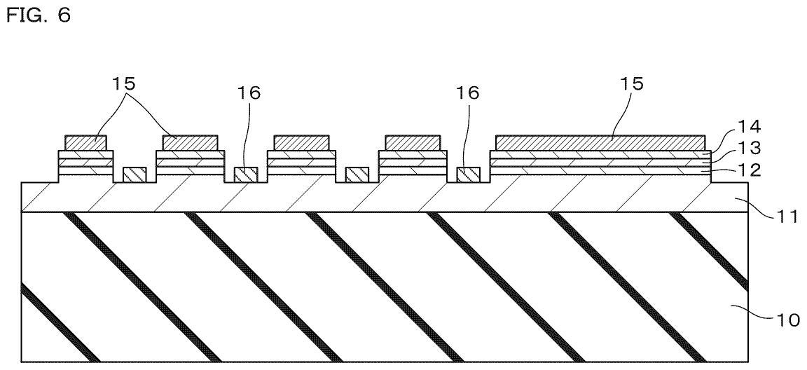

Then, the p-electrode 15 is formed on the p-type layer 14 by sputtering or vapor deposition (see FIG. 5). Then, a V layer, an Al layer, and a Ti layer are laminated in sequence by sputtering or vapor deposition on the n-type layer 11 that is exposed at the bottom of the holes 23 to thereby form the n-electrode 16 (see FIG. 6). The n-electrode 16 may be formed prior to the p-electrode 15 being formed. However, in order to form the p-electrode 15 under the condition where the surface of the p-type layer 14 is in a state as clean as possible, the p-electrode 15 is formed in first.

And then, heat treatment is performed at a temperature of 500 to 650° C. for 1 to 10 minutes. The atmosphere for performing the heat treatment is, for example, an atmosphere of an inert gas such as nitrogen. The heat treatment is preferably performed under reduced pressure, and the preferred pressure is in the range of, for example, 1×10² to 1×10⁴ Pa. The heat treatment temperature is preferably in the range of 550 to 650° C.

This heat treatment simultaneously performs an Mg activation treatment for the p-type layer 14 and reduction of contact resistance of the n-electrode 16.

In the embodiment, V/Al/Ti is used as the n-electrode 16 to lower the heat treatment temperature and perform the Mg activation treatment for the p-type layer 14 and reduction of contact resistances of the p-electrode 15 and the n-electrode 16 in common at a time, so that the number of the heat treatment is reduced. Lowering of the heat treatment temperature and reduction of the number of the heat treatment result in prevention of deterioration in electric property of the light emitting element.

Here, the above-mentioned heat treatment changes the n-electrode 16 structurally as mentioned below. V in V/Al/Ti which constitutes the n-electrode 16 diffuses into Al but does not diffuse into the n-type layer 11 and Ti. As the result of this diffusion, the V layer disappears. Al in V/Al/Ti reacts with N in the n-type layer 11 to thereby form AlNₓ at the interface between the n-type layer 11 and the Al layer. In this regard, it is conceivable that V functions to accelerate the reaction between Al and N like catalyst. This heat treatment changes the structure of the n-electrode 16 to a three-layer structure formed of a layer made of AlNₓ, a layer made of a metal including Al as a main component, V, and Ti, and a layer made of Ti.

Due to the structural change of the n-electrode 16, the contact resistance of the n-electrode 16 to the n-type layer 11 is reduced. The reason is as described before. That is, firstly, it is conceivable that the layer made of AlNₓ functions as an appropriate contact layer for the n-type layer 11. Secondly, it is conceivable that due to formation of AlNₓ, nitrogen vacancy generates on the surface of the n-type layer 11 whereby the n-type layer 11 more acceleratedly becomes n-type.

Next, the element isolation trench 26 is formed. The element isolation trench 26 has a depth sufficient for the substrate 10 being exposed. Then, the first protective film 18A which covers an entire upper surface of the element and is made of SiO₂ is formed (FIG. 7). The first protective film is deposited by vapor deposition or sputtering. From the viewpoint of denseness of the film, sputtering is preferred.

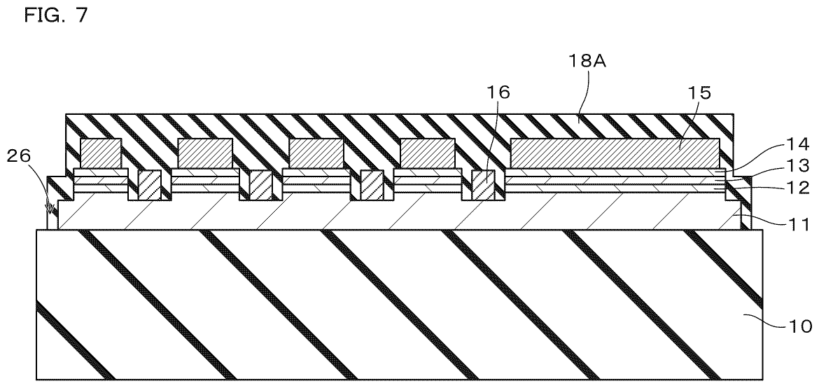

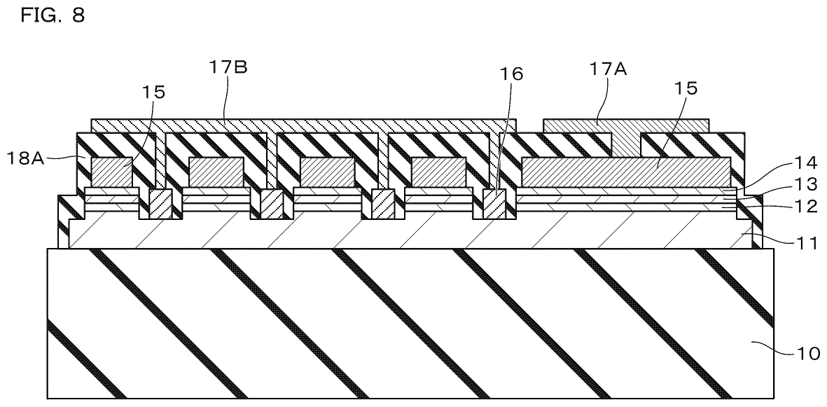

Then, holes are formed in the predetermined region of the first protective film 18A, and in this region, the PN electrodes 17A and 17B are further formed. The PN electrode 17A is connected to the p-electrode 15 through the hole, and the PN electrode 17B is connected to the n-electrodes 16 through the holes (see FIG. 8). The PN electrodes 17A and 17B are deposited by vapor deposition or sputtering, and are patterned by a lift-off method.

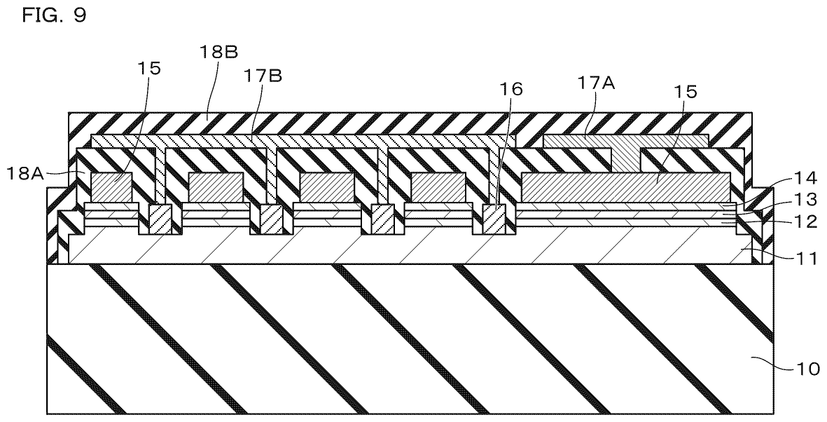

Then, on the first protective film 18A and the PN electrodes 17A and 17B, the second protective film 18B is formed. The first protective film 18A is deposited by vapor deposition or sputtering. From the viewpoint of denseness of the film, sputtering is preferred. In this way, the protective film 18 including the first protective film 18A and the second protective film 18B which are laminated in this order is formed (see FIG. 9). It is noted that the protective film 18 is preferably not formed at the bottom of the element isolation trench 26 and is preferably separated per element. This is to prevent pressure being applied on the protective film 18 and fluctuation being caused in the stress of the protective film 18 when dividing the protective film 18 per element.

Then, dry etching is performed on the predetermined region of the protective film 18 to thereby form the holes that reach the PN electrodes 17A and 17B. Subsequently, the p-pad electrode 20 and the n-pad electrode 21 are respectively formed on the protective film 18 such that the p-pad electrode 20 is connected to the PN electrode 17A through the corresponding hole and the n-pad electrode 21 is connected to the PN electrode 17B through the corresponding hole. The pattern of the p-pad electrode 20 and the n-pad electrode 21 is as shown in FIG. 2. The p-pad electrode 20 and the n-pad electrode 21 are deposited by vapor deposition or sputtering and are patterned by lift-off. Then, the antireflection film 22 is formed on the backside of the substrate 10. Subsequently, the substrate 10 is divided into individual elements. In this way, the light emitting element according to the embodiment shown in FIG. 1 is manufactured.

### 3. Experimental Result

Each experimental result in the embodiment will be described below.

### Experiment 1

Si substrates having SiO₂ and SiN respectively deposited thereon were prepared to compare the wet etching rates between SiO₂ and SiN. SiO₂ was deposited by three kinds of methods, i.e., CVD, sputtering, and heat oxidation (Samples B1, B2, and B3). On the other hand, SiN is deposited by CVD at the output of 100 w, 130 w, and 160 w (Samples A1, A2, and A3). In addition, SiN was deposited by CVD at the output of 160 w without feeding ammonia (Sample A4). Thicknesses of the SiO₂ film and the SiN film were respectively set to 320 nm.

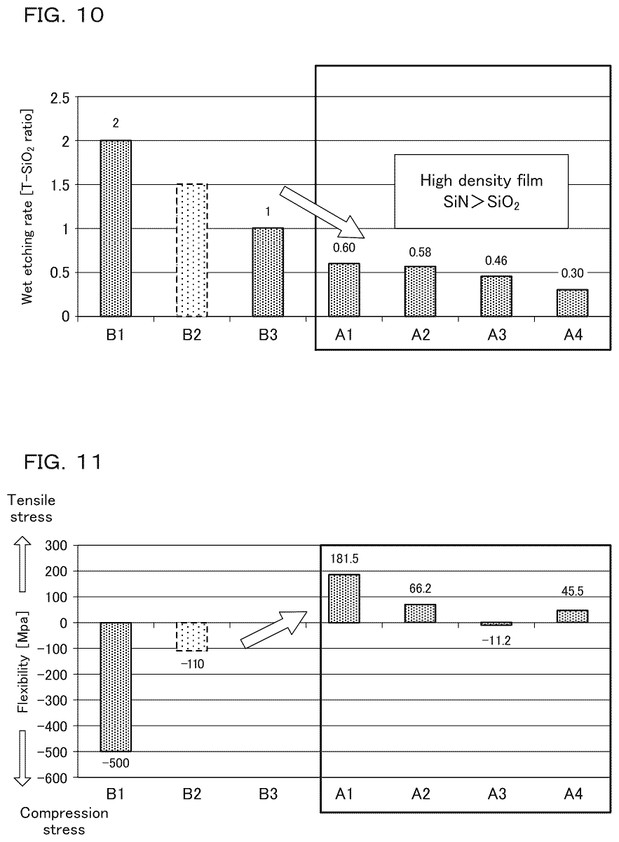

FIG. 10 is a graph showing a wet etching rate of each sample. The value of each wet etching rate is relative to the value in Sample B3 having SiO₂ deposited by heat oxidation, that is, each value was determined setting the wet etching rate in B3 as 1. As shown in FIG. 10, it was found that the wet etching rate in SiN was lower than that in SiO₂ and the SiN film was of high density. Thus, SiN was found to have a higher moisture proof property in comparison with SiO₂.

### Experiment 2

For Samples B1 and B2 having SiO₂ film deposited thereon, and Samples A1 to A4 having SiN film deposited thereon, a film stress of each sample was measured. FIG. 11 is a graph showing the film stress of each sample. As shown in FIG. 11, a compression stress generated in the SiO₂ film while a tensile stress generated in SiN film except for Sample A3. Thus, it was found that both stresses can be canceled each other due to lamination of SiO₂ and SiN to achieve reduction in stress.

### Experiment 3

Si substrates having SiO₂ and SiN respectively deposited thereon were prepared, and an Ag nanoparticle paste was applied thereon. Then, a minute force was applied to the applied nanoparticle paste to examine adhesion of the Ag nano-paste.

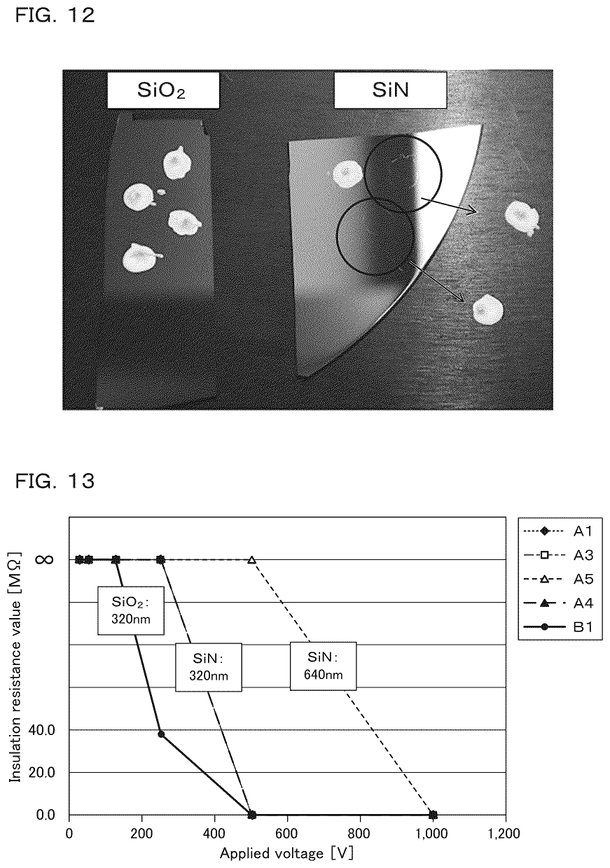

FIG. 12 is a photograph of the surface of the substrate on which an Ag nanoparticle paste had been applied. As shown in FIG. 12, when an Ag nanoparticle paste was applied on the SiO₂ film, the Ag nanoparticle paste was adhered firmly thereto without peel-off. This is considered because the Ag nanoparticle paste infiltrates into the SiO₂ film from a crack and/or a pinhole in the SiO₂ film and serves as an anchor for adhesion. In contrast, when the Ag nanoparticle paste was applied on the SiN film, the Ag nanoparticle paste was hardly adhered to the SiN film and was peeled off with a minute force. This is considered because the number of cracks and/or pinholes in SiN is few and the Ag nanoparticle paste does not infiltrate into the SiN film. Consequently, it was found that SiN was excellent in moisture resistance and solvent resistance in comparison with SiO₂.

### Experiment 4

Sample B2 having SiO₂ deposited by sputtering and Samples A1, A3 to A5 having SiN deposited by CVD were prepared, and a voltage was applied between the surface of SiO₂ or Sin and the backside of the Si substrate to measure an insulation resistance. Sample 5 was prepared such that SiN was deposited on the Si substrate by CVD at 160 W, the thickness of which was set to 640 nm.

FIG. 13 is a graph showing a relation between an applied voltage and an insulation resistance value in each sample. A voltage applied at the time when the insulation resistance value starts to drop is a withstand pressure. As can be seen from FIG. 13, the withstand pressure of Sample B1 was 125V whereas the withstand pressures of Samples A1, A3, and A4 were 250V. It was found from this result that the withstand pressure of SiN was twice that of SiO₂ deposited by sputtering in the comparison on condition of having the same thickness. The withstand pressure of Sample 5 was 500V. It was found from this result that when the thickness of SiN was set to twice, the withstand pressure of SiN was also approximately doubled.

### Experiment 5

Samples B2, A1, and A3 to A5 used in Experiment 4 were prepared in the same way. An Ag nanoparticle paste was applied on the SiO₂ film or the SiN film of each sample, and a voltage was applied between the Ag nanoparticle paste and the backside of the Si substrate to measure an insulation resistance. In a similar way, an insulation resistance in the case of forming an Ag film on the SiO₂ film or the SiN film by sputtering was measured.

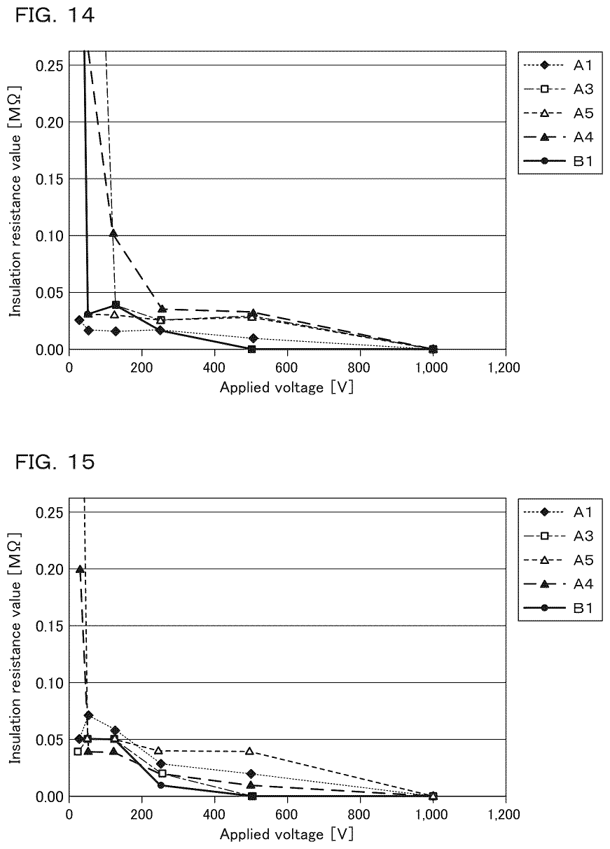

FIG. 14 is a graph showing a relation between an applied voltage and an insulation resistance value in each sample having an Ag nanoparticle paste applied thereto. As can be seen from FIG. 14, the insulation resistances of Samples A3 to A5 were higher than that of Sample B1 at an applied voltage of around 300 to 400V.

FIG. 15 is a graph showing a relation between an applied voltage and an insulation resistance value in each sample having an Ag film deposited thereon. As can be seen from FIG. 15, the insulation resistances of Samples A1, and A3 to A5 were higher than that of Sample B2 at an applied voltage of around 300 to 400V. Further, the insulation resistance of Sample A5 was higher than those of A1, A3, and A4, and thus, it was found that the thicker SiN is made, the higher the insulation resistance becomes.

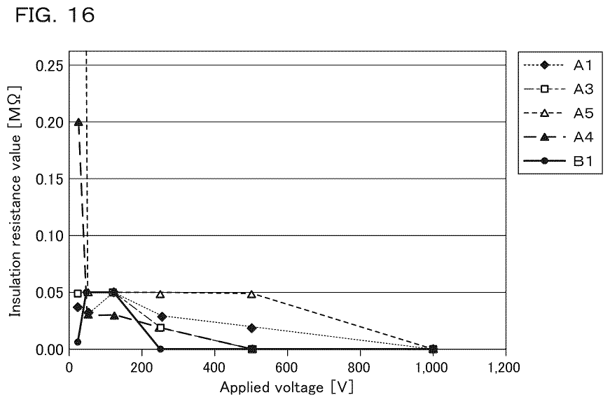

FIG. 16 is a graph showing a relation between an applied voltage and an insulation resistance value in each sample having a Ti film deposited thereon. As can be seen from FIG. 16, it was found that the relation has a similar tendency to that shown in FIG. 15. Specifically, the insulation resistances of Samples A1, and A3 to A5 were higher than that of Sample B2 at an applied voltage of around 300 to 400V. Further, the insulation resistance of Sample A5 was higher than those of A1, A3, and A4, and thus, it was found that the thicker SiN is made, the higher the insulation resistance becomes.

As can be seen from FIGS. 14 to 16, it was found that SiN deposited by CVD was higher than SiO₂ deposited by sputtering in insulation resistance, and the thicker SiN is made, the higher the insulation resistance becomes. From the experimental results shown in FIGS. 14 to 16, it was found that SiN was preferably made thicker from the viewpoint of preventing current leakage, and the thickness of SiN was preferably 320 nm or more, and more preferably 640 nm or more.

What is claimed is:

1. A light emitting element having an emission wavelength of 200 to 280 nm and including a group-III nitride semiconductor containing Al, the element, comprising:
a substrate;
a semiconductor layer including an n-type layer, a light emitting layer, and a p-type layer which are laminated on the substrate in this order;
a hole provided in a predetermined region of a surface of the p-type layer, the hole having a depth reaching the n-type layer;
a p-electrode provided on the p-type layer in contact therewith, the p-electrode including one of a Ru layer, a Rh layer, a Ni Layer, and an ITO layer;
an n-electrode provided on the n-type layer exposed at a bottom of the hole; and
a protective film covering an entire upper surface of the element, the protective film including a first protective film made of SiO₂ and a second protective film made of SiN which are laminated in this order from a side of the substrate.

2. The light emitting element according to claim 1, further comprising a reflection film between the first protective film and the second protective film, the reflection film including Al or an alloy mainly composed of Al.

3. The light emitting element according to claim 1, wherein
the hole is formed plurally and a plurality of the holes are arranged in a pattern of a square lattice, a triangular lattice, or a honeycomb; and
the n-electrode is formed on a bottom of each hole.

4. The light emitting element according to claim 1, wherein the second protective film has a thickness of 320 nm or more.

5. The light emitting element according to claim 1, wherein a thickness ratio of the second protective film to the first protective film falls within a range of 0.5 to 2.

6. The light emitting element according to claim 1, wherein the n-electrode includes:
a first layer at a position in contact with the n-type layer, the first layer being made of AlNₓ, or Al_{y}Ga_{1-y}Nₓ having an Al composition higher than that of the n-type layer and having a thickness of 1 nm or more and 3 nm or less, and
a second layer at a position in contact with the first layer, the second layer being made of metal including Al as a main component and V and having a thickness of 50 nm or more and 500 nm or less.

7. The light emitting element according to claim 1, for use in water sterilization or in air sterilization in a high-humidity environment.
